(19) United States
(12) Patent Application Publication
(10) Pub. No.: US 2014/0027620 A1
(43) Pub. Date: Jan. 30, 2014

(54) SOLID-STATE IMAGE PICKUP DEVICE AND IMAGE PICKUP APPARATUS

(71) Applicant: Nobuhiro Takeda, Yokohama-shi (JP)

(72) Inventor: Nobuhiro Takeda, Yokohama-shi (JP)

(21) Appl. No.: 14/110,929

(22) PCT Filed: Mar. 13, 2012
(86) PCT No.: PCT/JP2012/056952

§ 371 Date: Oct. 10, 2013

(30) Foreign Application Priority Data
Apr. 15, 2011 (JP) 2011-090932

(51) Int. Cl. H04N 5/378

(52) U.S. Cl. CPC H04N 5/378
USPC 250/208.1

(57) ABSTRACT

A solid-state image pickup device is provided that is capable of effectively reducing color noise caused due to differences between sensitivities of color filters of an optical filter. The image pickup device includes a plurality of pixels arranged in a two dimensional matrix to respectively correspond to color filters. Pixels in odd-numbered rows of respective columns are connected to first column output lines, and pixels in even-numbered rows of respective columns are connected to second column output lines. First and second column units are provided to respectively correspond to the first and second column output lines, and amplify pixel signals output from these column output lines at gains that are set to different values according to the color filters.

### TECHNICAL FIELD

The present invention relates to a solid-state image pickup device and an image pickup apparatus using the same.

### BACKGROUND ART

In recent years, a CMOS image pickup device has often been used as a solid-state image pickup device of an image pickup apparatus such as a digital camera. The CMOS image pickup device is advantageous, for example, in high signal-to-noise ratio (S/N) and low power consumption and in that peripheral circuits, etc. can be implemented on-chip. To enhance functionality, however, an image pickup apparatus typified by a digital camera is demanded to have high sensitivity and low noise.

As an image pickup apparatus with reduced noise, there can be mentioned, for example, an image pickup apparatus in which color components of an analog video signal output from a solid-state image pickup device are amplified by variable gain amplifiers, color components of the amplified analog video signal are quantized by A/D converters, and quantization input levels of the A/D converters are adjusted by a gain decision circuit by variably setting amplifier gains, thereby reducing quantum noise (see, for example, PTL 1 described below).

Another image pickup apparatus has been proposed for preventing a reduction in accuracy of a signal value read out at high speed from a solid-state image pickup device. In this apparatus, analog values input from analog value input terminals are stored into an analog value storage unit and input to respective one input terminals of comparators, and reference values from D/A converters that gradually increase with the progress of a counter operation are input to respective other input terminals of the comparators. When each of the analog values becomes smaller than the corresponding reference value, counter data is stored into a digital value storage unit. Subsequently, pieces of counter data are sequentially read out as digital values from the digital value storage unit by a scanning circuit (see, for example, PTL 2 described below).

### CITATION LIST

### Patent Literature

{PTL 1} Japanese Laid-open Patent Publication No. 2001-309393

{PTL 2} Japanese Laid-open Patent Publication No. H5-48460

### SUMMARY OF INVENTION

### Technical Problem

The image pickup apparatus disclosed in PTL 1, which is for correcting white balance, requires variable gain amplifiers for respective color components of the analog video signal and is required to adjust the respective gains of these amplifiers according to light irradiated onto an object.

In this image pickup apparatus, noise tends to be superimposed onto the analog video signal output from the solid-state image pickup device until the analog video signal is input to the variable gain amplifiers disposed downstream of the image pickup device. Since color components of the analog video signal superimposed with noise are amplified by the variable gain amplifiers, the noise is inevitably amplified.

In particular, in the case of high-sensitivity photographing where the color components of the video signal are amplified with high gains by the variable gain amplifiers, the video signal is noticeably affected by the noise.

The present invention provides a solid-state image pickup device and an image pickup apparatus, which are capable of effectively reducing color noise caused due to differences between sensitivities for respective colors of an optical filter.

### Solution to Problem

Accordingly, a first aspect of this invention provides a solid-state image pickup device that includes a plurality of pixels arranged in a two dimensional matrix to respectively correspond to optical filters for a plurality of colors and includes column output lines to which pixel signals are output from pixels in respective columns in the plurality of pixels, comprising column amplification units provided to respectively correspond to the column output lines for the respective columns and configured to amplify the pixel signals for output to the column output lines, wherein gains of the column amplification units are set to different values according to the colors of the optical filters.

Accordingly, a second aspect of this invention provides an image pickup apparatus comprising the solid-state image pickup device described in the first aspect, a noise removal unit configured to remove noise from an image signal output from the solid-state image pickup device, a gain adjustment unit configured to perform a gain adjustment on an output of the noise removal unit, and an analog-to-digital conversion unit configured to perform analog-to-digital conversion on an output of the gain adjustment unit to obtain image data.

The features and advantages of the invention will become more apparent from the following detailed description taken in conjunction with the accompanying drawings.

### Advantageous Effects of Invention

According to this invention, it is possible to effectively reduce color noise caused due to differences between sensitivities for respective colors of the optical filter, making it possible to obtain a satisfactory photographed image, especially, at the time of high-sensitivity photographing.

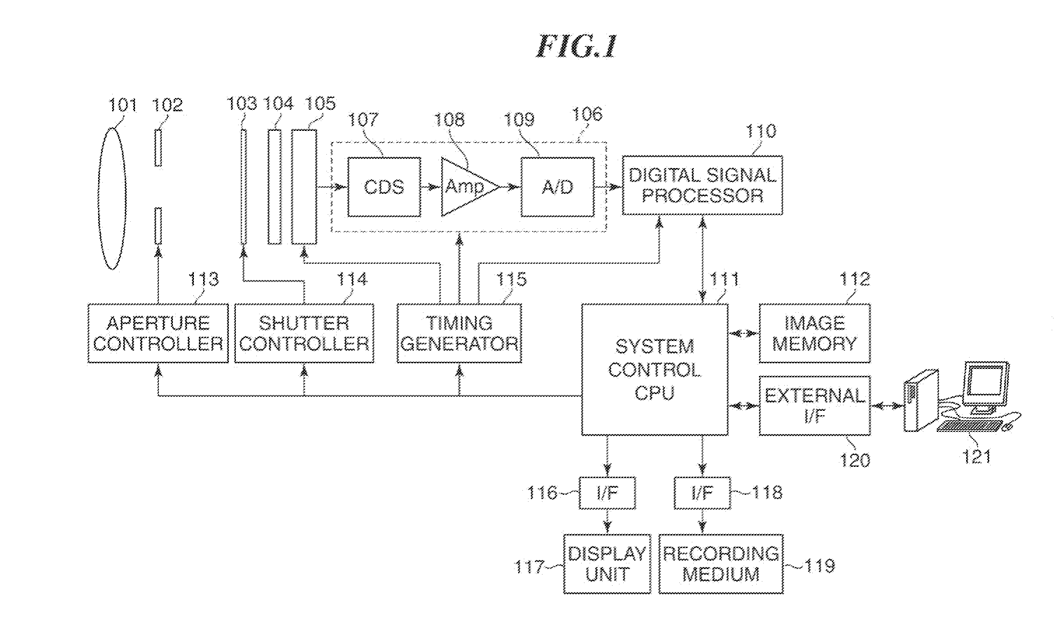

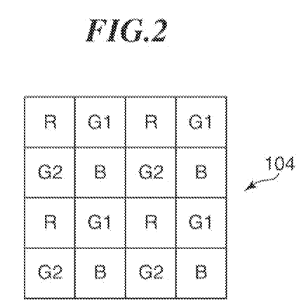

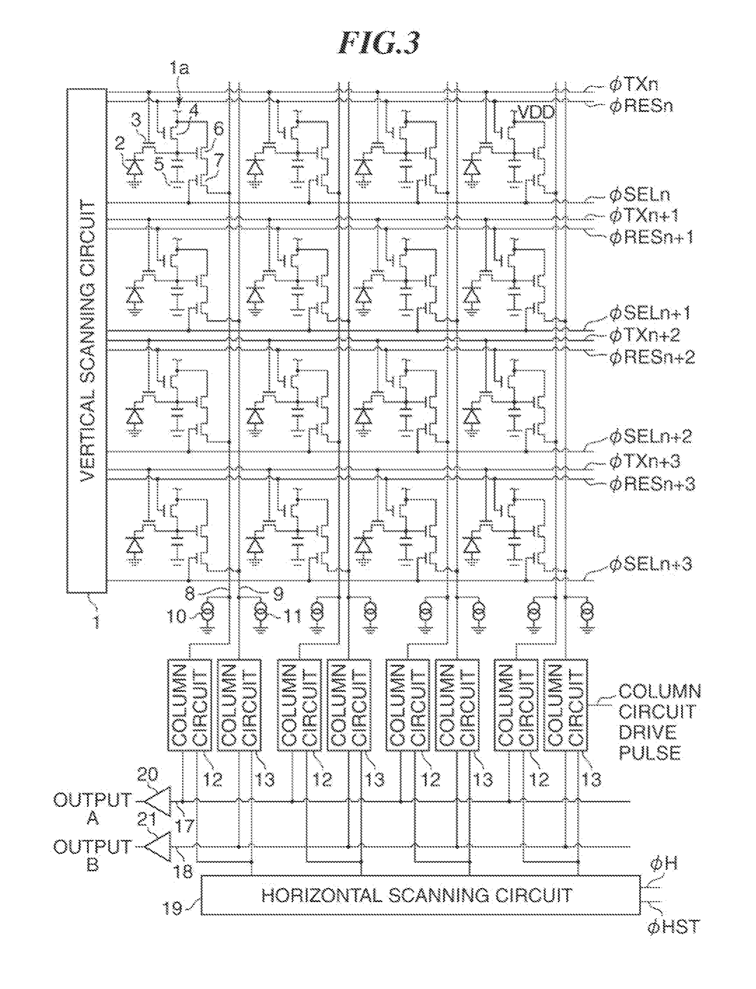

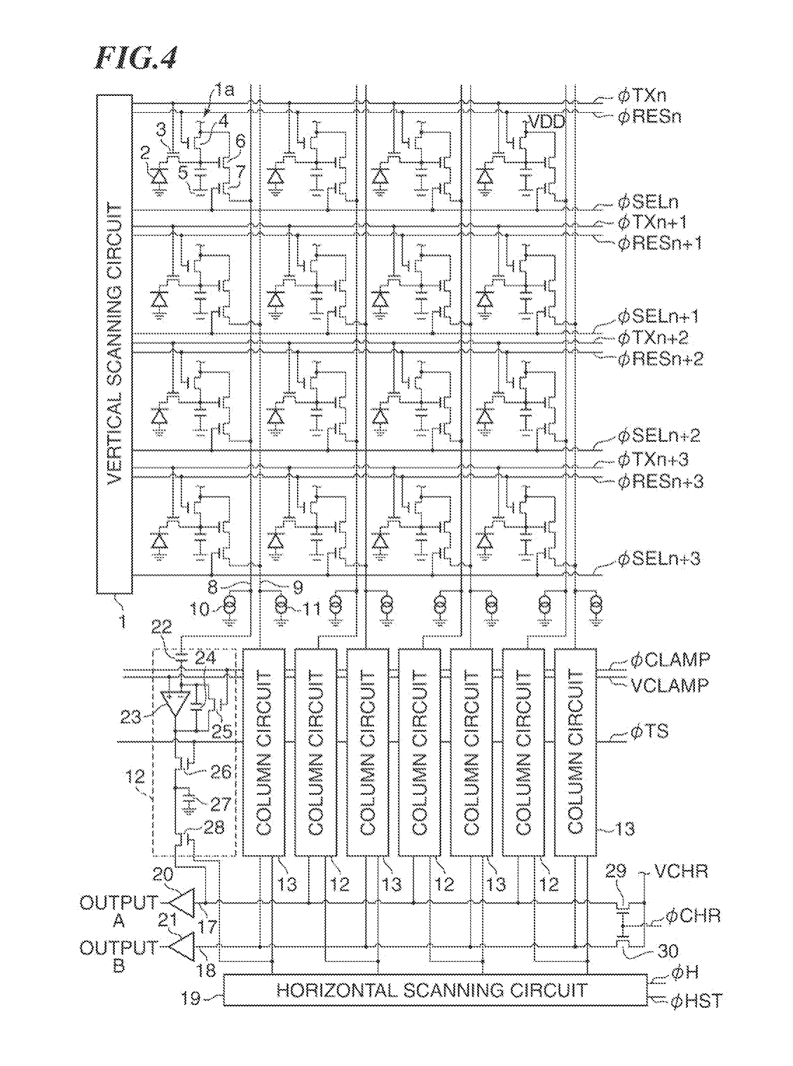

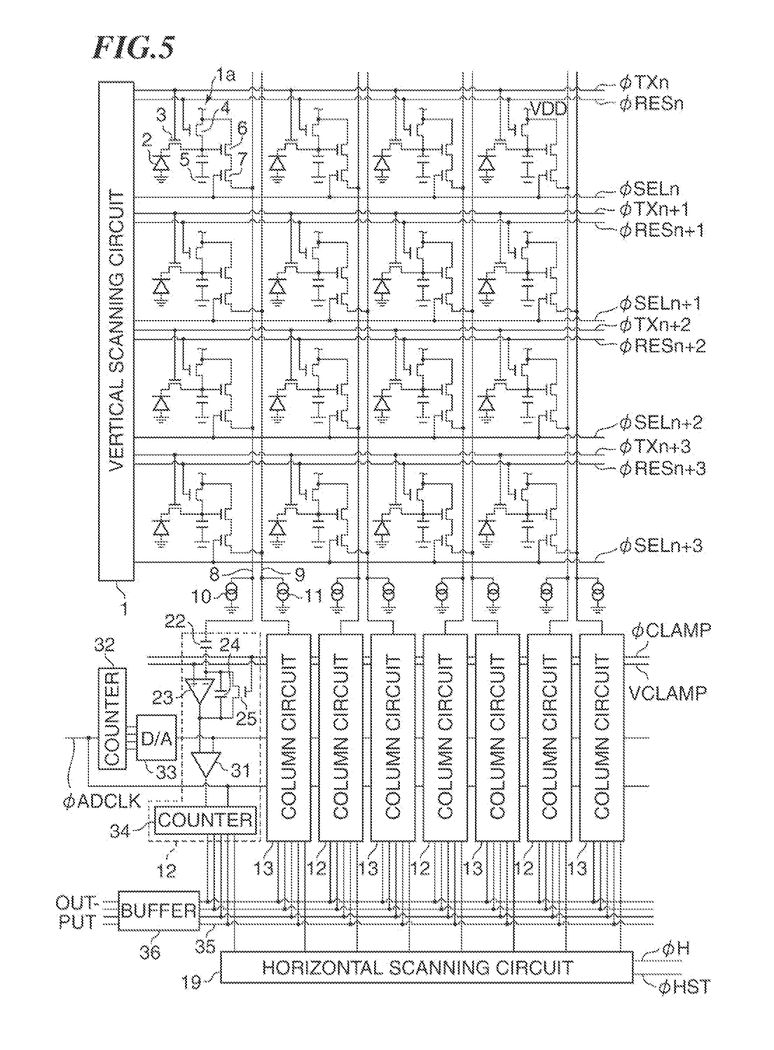

### BRIEF DESCRIPTION OF DRAWINGS

[FIG. 1] A block diagram showing an example of an image pickup apparatus according to one embodiment of this invention.

[FIG. 2] A view showing an example arrangement of a color filter of the image pickup apparatus.

[FIG. 3] A view showing an example construction of a solid-state image pickup device of the image pickup apparatus.

[FIG. 4] A view similar to FIG. 3 and showing in detail an example internal construction of a column circuit of the solid-state image pickup device.

[FIG. 5] A view similar to FIGS. 3 and 4 and showing another example construction of the column circuit of the solid-state image pickup device.

### DESCRIPTION OF EMBODIMENTS

The present invention will be described below with reference to the drawings showing an example of an image pickup apparatus according to one embodiment thereof.

FIG. 1 shows in block diagram an example image pickup apparatus according to one embodiment of this invention.

The image pickup apparatus shown in FIG. 1 is a digital still camera in which the amount of light passing through a lens 101 is adjusted by an aperture 102, light passes through a mechanical shutter 103 and an optical filter 104, and an optical image is formed on a solid-state image pickup device (hereinafter, referred to as the image pickup device) 105 such as a CMOS image pickup device.

The aperture 102 is controlled by an aperture controller 113, and the mechanical shutter 103 is controlled by a shutter controller 114 to control incidence of light into the image pickup device 105. The optical filter 104 is disposed upstream of the image pickup device 105 and limits the wavelength or spatial frequency of the incident light to the image pickup device 105.

It should be noted that although the optical filter 104 is disposed upstream of the image pickup device 105 in the illustrated example, the optical filter 104 can be incorporated in the image pickup device 105.

The image pickup device 105 outputs to an analog front end (AFE) 106 an image signal (analog signal) corresponding to the optical image. The AFE 106 performs predetermined analog processing (e.g., noise removal and gain adjustment) on the image signal and performs analog-to-digital (A/D) conversion of the image signal.

In the illustrated example, the AFE 106 includes a CDS (co-related double sampling) circuit 107 for removing noise from the image signal, a gain adjustment amplifier 108 for adjusting a signal gain, and an A/D converter 109 for converting the output of the amplifier 108 into a digital signal (image data).

It should be noted that the AFE 106 is omitted in a case where the image pickup device 105 outputs the image signal in digital form.

The output from the AFE 106 (i.e., image data) is supplied to a digital signal processor 110 that performs various correction processing and compression processing on the image data. The image data output from the digital signal processor 110 is supplied to a system control CPU (hereinafter, sometimes referred to as the CPU) 111 that causes an image memory 112 to temporarily store the image data.

The CPU 111 performs various processing and controls the entire digital still camera. Under the control of the CPU 111, a timing generator 115 outputs timing signals to the image pickup device 105, the AFE 106, and the digital signal processor 110. The aperture controller 113 and the shutter controller 114 are controlled by the CPU 111.

In the illustrated example, the system control CPU 111 is connected through a display interface (I/F) 116 to a display unit 117 and connected through a recording I/F 118 to a recording medium 119. The CPU 111 can also be connected through an external I/F 120 to an external device 121 such as a personal computer (PC).

The display unit 117 is a liquid crystal display, for example, and displays an image based on image data supplied from the system control CPU 111. The CPU 111 records image data in the recording medium 119, and reads out image data recorded therein. The recording medium 119 can be detachably mounted to the I/F 118 (i.e., to the digital still camera) and is implemented by a semiconductor memory, for example.

The following is a description of operation of the digital still camera. When a power switch (not shown) is turned on, a main power source is turned on, whereby power supply to a control system is turned on and power supply to image pickup system circuits such as the AFE 106 is also turned on.

Next, the system control CPU 111 causes the aperture controller 113 to open the aperture 102 for control of exposure amount, and causes the shutter controller 114 to open the mechanical shutter 103. As a result, the image pickup device 105 outputs an analog signal corresponding to incident light.

The analog signal output from the image pickup device 105 is converted into image data by the AFE 106 and then supplied to the digital signal processor 110. The system control CPU 111 performs exposure computation (i.e., light measurement processing) based on image data supplied from the digital signal processor 110. The system control CPU 111 determines brightness according to a result of the light measurement processing and controls the aperture 102.

Next, the system control CPU 111 performs distance measurement processing in which a high-frequency component is extracted from the image data supplied from the digital signal processor 110 and a distance to object is determined. Then, the CPU 111 causes a lens drive unit (not shown) to drive the lens 101 according to a result of the distance measurement, and determines whether an in-focus state is established. When determining that an in-focus state is not established, the CPU 111 again performs the distance measurement processing and causes the lens drive unit to drive the lens 101.

When determining that an in-focus state is established, the CPU 111 causes an electronic shutter of the image pickup device 105 to perform main exposure. It should be noted that the main exposure can also be performed by opening and closing the mechanical shutter 103.

After completion of the exposure, the system control CPU 111 controls the timing generator 115 to sequentially output pixel signals for respective rows, as an image signal. To output the image signal, the image pickup device 105 is set beforehand at a drive mode by a selection circuit (not shown). At that time, an all-pixel readout mode or an addition readout mode can be selected by the selection circuit.

In the AFE 106, noise superimposed on the image signal output from the image pickup device 105 is removed by, e.g., the co-related double sampling by the CDS circuit 107, and the resultant image signal is amplified by the amplifier 108. Subsequently, the image signal is A/D converted (analog-to-digital converted) by and output from the A/D converter 109.

Next, the image data processed by the digital signal processor 110 is supplied to the system control CPU 111 that writes the image data into the image memory 112. Under the control of the CPU 111, the image data stored in the memory 112 is recorded into the recording medium 119 through the recording I/F 118.

Under the control of the CPU 111, the image data obtained as described above is also supplied through the display I/F 116 to the display unit 117 on which an image is displayed based on the image data. It should be noted that the CPU 111 can directly supply the image data to the PC 121 through the external I/F 120.

FIG. 2 shows an example arrangement of the optical filter 104.

In FIG. 2, the optical filter 104 has a plurality of color filters that are arranged in a so-called Bayer arrangement.

In the illustrated example, the optical filter 104 has two first lines (rows) in each of which red color filters (R filters) and first green color filters (G1 filters) are alternately arranged and has two second lines in each of which second green color filters (G2 filters) and blue color filters (B filters) are alternately arranged. These first and second lines are alternately arranged in the column direction.

FIG. 3 shows an example construction of the image pickup device 105.

Referring to FIG. 3, the image pickup device 105 has a plurality of pixels 1a that are arranged in a two dimensional matrix of n rows and m columns (n and m are integer equal to or greater than 2). It should be noted that n and m are each equal to 4 in the illustrated example.

Each of the pixels 1a includes a photodiode (PD) 2, transfer switch 3, reset switch 4, floating diffusion (FD) 5, source follower amplifier 6, and row selection switch 7. The row selection switch 7 is connected to a vertical output line (first or second column output line) 8 or 9.

It should be noted that a power source voltage (not shown) is connected to the reset switch 4 and to the source follower amplifier 6.

The PD 2 generates and stores a signal charge according to the amount of incident light. The transfer switch 3 transfers, to the FD 5, the signal charge stored in the PD 2. The reset switch 4 resets an unnecessary charge stored in the PD 2 or stored in the FD 5. The source follower amplifier 6 amplifies and converts the signal charge stored in the FD 5 into a voltage signal. An output terminal of the source follower amplifier 6 is connected through the row selection switch 7 to the vertical output line 8 or 9.

It should be noted that in the illustrated example, the reset switch 4, FD 5, and source follower amplifier 6 constitute a floating diffusion amplifier.

In the image pickup device 105 of FIG. 3, the source follower amplifiers 6 in odd-numbered rows have output terminals connected to the vertical output lines (first column output lines) 8, whereas the source follower amplifiers 6 in even-numbered rows have output terminals connected to the vertical output lines (second column output lines) 9.

Load current sources 10, 11 are connected to respective ones of the vertical output lines 8, 9. Each of the load current sources 10, 11 is for driving the source follower amplifiers 6 in that row selected by a corresponding row selection switch 7.

In the pixels 1a in the first row, the transfer switches 3 are turned on and off in accordance with a transfer pulse φTXn, the reset switches 4 are turned on and off in accordance with a reset pulse φRESn, and the row selection switches 7 are turned on and off in accordance with a row selection pulse φSELn. Signal charges stored in the PDs 2 are transferred to the FDs 5 when the transfer switches 3 are turned on, the PDs 2 or the FDs 5 are reset when the reset switches 4 are turned on, and output terminals of the source follower amplifiers 6 are connected to the vertical output lines 8 when the row selection switches 7 are turned on.

Similarly, the pixels 1a of the second row are controlled in accordance with a transfer pulse φTXn+1, reset pulse φRESn+1, and row selection pulse φSELn+1. The pixels 1a of the third row are controlled in accordance with a transfer pulse φTXn+2, reset pulse φRESn+2, and row selection pulse φSELn+2. The pixels 1a of the fourth row are controlled in accordance with a transfer pulse φTXn+3, reset pulse φRESn+3, and row selection pulse φSELn+3.

It should be noted that the transfer pulses φTXn to φTXn+3, reset pulses φRESn to φRESn+3, and row selection pulses φSELn to φSELn+3 are output from a vertical scanning circuit (column scanning circuit) 1.

The vertical output lines (first column output lines) 8 are connected to column circuits 12 for processing pixel signals output from the pixels 1a in odd-numbered rows of respective columns, and the vertical output lines (second column output lines) 9 are connected to column circuits 13 for processing pixel signals output from the pixels 1a in even-numbered rows of respective columns. The column circuits 12, 13 are each supplied with a column circuit drive pulse. The construction of the column circuits 12, 13 will be described later.

The column circuits 12, 13 are connected to a horizontal scanning circuit (row scanning circuit) 19 to which a horizontal scanning clock (row scanning clock) φH and a signal φHST are supplied. The signal φHST represents start of a horizontal scanning period (row scanning period). In other words, the signal φHST represents start of output of output signals of respective columns to horizontal readout lines (row readout lines) 17, 18. In accordance with the horizontal scanning clock φH, the horizontal scanning circuit 19 outputs the output signals of the column circuits 12, 13 to respective ones of the horizontal readout lines 17, 18.

The horizontal readout lines 17, 18 are connected to output amplifiers 20, 21 (amplifier units), respectively. The output amplifier 20 amplifies the output signals of the column circuits 12 (i.e., pixel signals of odd-numbered rows) which are output to the horizontal readout line 17, and outputs the amplified signals as an output A. The output amplifier 21 amplifies the output signals of the column circuits 13 (i.e., pixel signals of even-numbered rows) which are output to the horizontal readout line 18, and outputs the amplified signals as an output B. The outputs A, B of the output amplifiers 20, 21 correspond to image signals for respective colors.

In the case of using the optical filter 104 having color filters of Bayer arrangement shown in FIG. 2, R signals and G2 signals (i.e., pixel signals output from the R filters and G2 filters) are respectively processed by the column circuits 12, 13 in the first column, and G1 signals and B signals (i.e., pixel signals output from the G1 filters and B filters) are respectively processed by the column circuits 12, 13 in the second column. Similarly, R signals, G2 signals, G1 signals, and B signals are respectively processed by the column circuits 12, 13 in the third and fourth columns. It is therefore possible to optimally amplify the pixel signals for respective colors output from the optical filter 104.

It should be noted that although the first and second green color filters are employed in the example shown in FIG. 2, one green color filters can be used instead.

FIG. 4 is similar to FIG. 3 and shows in detail an example internal construction of one of the column circuits 12 of the image pickup device 105. It should be noted that the column circuits 13 are the same in construction as the column circuit 12 shown in FIG. 4. In FIG. 4, like elements which are the same as those shown in FIG. 3 are denoted by like numerals, and a description thereof will be omitted.

As shown in FIG. 4, horizontal output line reset switches 29, 30 (not shown in FIG. 3) are respectively connected to the horizontal readout lines 17, 18, and have gates thereof connected to each other. The reset switches 29, 30 are turned on and off according to a signal φCHR applied to the gates of the switches 29, 30. The horizontal readout lines (row readout lines) 17, 18 are reset to a voltage VCHR each time the horizontal scanning clock (row scanning clock) φH is supplied to the horizontal scanning circuit 19.

The column circuits 12 of respective columns are the same in construction as one another and each include a clamp capacitance 22, a column amplifier 23, a feedback capacitance 24, and a clamp switch 25. In FIG. 4, the internal construction of only one of the column circuits 12 is shown, while omitting the illustration of that of the other column circuits 12. A signal φCLAMP, a clamp voltage VCLAMP, and a signal φTS are supplied, as the column circuit drive pulse, to the column circuits 12.

It should be noted that the clamp capacitance 22, column amplifier 23, feedback capacitance 24, and clamp switch 25 of one column circuit 12 constitute a first or a second column amplification unit.

Each of the vertical output lines 8 is connected through the clamp capacitance 22 to an inverting input terminal of the corresponding column amplifier 23. The inverting input terminal is connected through the feedback capacitance 24 to an output terminal of the column amplifier 23. The gain of the column amplifier 23 is determined according to a ratio between the clamp capacitance 22 and the feedback capacitance 24. The inverting input terminal and the output terminal of the column amplifier 23 are connected to each other through the clamp switch 25, which is controlled according to the signal φCLAMP. The clamp voltage VCLAMP is applied to a non-inverting input terminal of the column amplifier 23.

An output signal of the column amplifier 23 is transferred to and stored (accumulated) in a transfer capacitance 27 through a transfer gate 26, which is controlled to be turned on and off in accordance with the signal φTS. The output signal stored in the transfer capacitance 27 is output to the horizontal readout line 17 through a transfer gate 28 (readout switch), which is controlled to be turned on and off by the horizontal scanning circuit 19 in accordance with the horizontal scanning clock (row scanning clock) φH. The output signal of the column amplifier 23 is read out from the transfer capacitance 27 to the horizontal output line 17 by capacitance division between the transfer capacitance 27 and a parasitic capacitance of the horizontal output line 17.

The gains of the column circuits 12, 13 of respective columns are respectively optimized for the color filters of the optical filter 104. To optimize the gains of the column circuits 12, 13, the gains of the column circuits 12, 13 are determined, for example, such that outputs of the column circuits 12, 13 are made at the same level as one another based on transmittance of the optical filter 104 and spectral sensitivity of the image pickup device 105, which are measured beforehand by using a reference optical source. In general, the thus determined gains of the column circuits 12, 13 are different from one another. In other words, the gains of the column circuits 12, 13 can be optimized by making the gains of the column circuits 12, 13 different from one another.

As the method for optimizing the gains of the column circuits 12, 13 by making the gains of the column circuits 12, 13 different from one another, there can be mentioned a method for determining the clamp capacitances 22 and/or the feedback capacitances 24 and/or the transfer capacitances 27 of the column circuits 12, 13 to optimum values which are different from one another.

FIG. 5 is similar to FIGS. 3 and 4 and shows another example of the internal construction of one of the column circuits 12. It should be noted that the column circuits 13 are the same in construction as the column circuit 12 shown in FIG. 5. In FIG. 5, like elements which are the same as those shown in FIGS. 3 and 4 are denoted by like numerals, and a description thereof will be omitted.

The column circuits 12 of respective columns are the same in construction as one another and each include the clamp capacitance 22, column amplifier 23, feedback capacitance 24, and clamp switch 25. In FIG. 5, the internal construction of only one of the column circuits 12 is shown, while omitting the illustration of that of the other column circuits 12. The column amplifier 23 of the column circuit 12 has an output terminal connected to one of input terminals of a voltage comparator 31 whose output terminal is connected to a counter 34. An output terminal of the counter 34 is connected to one of digital signal output lines 35 which are connected to an output buffer 36. It should be noted that the voltage comparator 31 and the counter 34 serve as a second counter unit.

The image pickup device 105 includes a column D/A circuit 33 (ramp output unit) for the column circuits 12 that has an output terminal connected to another input terminal of the voltage comparator 31. A counter 32 (first counter unit) is connected to the column D/A circuit 33. It should be noted that the column D/A circuit 33 is a ramp-type D/A circuit (which is similar to one disclosed in PTL 2) and outputs a ramp waveform output.

The counter 32 counts a clock signal φADCLK and supplies a count value to the column D/A circuit 33. The column D/A circuit 33 outputs an analog signal (voltage signal) corresponding to the count value. The voltage comparator 31 compares an output voltage supplied from the column amplifier 23 with an output voltage supplied from the column D/A circuit 33, and outputs a comparison result. For example, an output of the voltage comparator 31 representing the comparison result varies when the output voltages compared by the voltage comparator 31 coincide with each other. In accordance with the output of the voltage comparator 31, the counter 34 stops counting the clock signal φADCLK and holds a count value at that time. Thus, the output of the column amplifier 23 is A/D converted into a digital value, which is then held in the counter 34.

When one of the column circuits 12 is selected by the horizontal scanning circuit 19, a digital value held in the counter 34 of the selected column circuit 12 is output to the digital signal output line 35. The digital value is then converted into an image signal by the output buffer 36 (output unit) from which the image signal is output.

Also in the example construction shown in FIG. 5, the gains of the column circuits 12, 13 in respective columns are made different from one another and optimized according to the optical filter 104. As with the case of FIG. 4, the gains of the column circuits 12, 13 can be optimized by, for example, determining the gains of the column circuits such that outputs of the column circuits are made at the same level as one another.

As the method for optimizing the gains of the column circuits 12, 13 by making the gains of the column circuits 12, 13 different from one another, there can be mentioned, for example, a method for determining the clamp capacitances 22, etc. of the column circuits 12, 13 to optimum values which are different from one another (as with the case of FIG. 4) and a method for determining slopes of ramp waveforms output from the D/A converters 33 for the column circuits 12, 13 to different optimum values according to the color filters of the optical filter 104.

As described above, according to this embodiment, the gains of the column circuits 12, 13 are made different and optimized according to the color filters of the optical filter 104, and pixel signals for respective colors are amplified by the column circuits 12, 13 with the optimum gains at a stage where the pixel signals are less affected by noise. It is therefore possible to effectively reduce color noise caused due to differences between the sensitivities of the color filters for respective colors. Thus, a satisfactory photographed image can be obtained even at high-sensitivity photographing.

While the present invention has been described with reference to an exemplary embodiment, it is to be understood that the invention is not limited to the disclosed exemplary embodiment. The scope of the following claims is to be accorded the broadest interpretation so as to encompass all such modifications and equivalent structures and functions.

### REFERENCE SIGNS LIST

2 Photodiode

3 Transfer switch

4 Reset switch

5 Floating diffusion

6 Source follower amplifier

7 Row selection switch

8, 9 Vertical output line (column output line)

12, 13 Column circuit

17, 18 Horizontal readout line (row output line)

23 Column amplifier

1. A solid-state image pickup device that includes a plurality of pixels arranged in a two dimensional matrix to respectively correspond to optical filters for a plurality of colors and includes column output lines to which pixel signals are output from pixels in respective columns in the plurality of pixels, comprising:
column amplification units provided to respectively correspond to the column output lines for the respective columns and configured to amplify the pixel signals for output to the column output lines,
wherein gains of said column amplification units are set to different values according to the colors of the optical filters.

2. The solid-state image pickup device according to claim 1, wherein each of said column amplification units has a clamp capacitance connected to a corresponding one of the column output lines, a column amplifier having an inverting input terminal connected to the clamp capacitance and a non-inverting input terminal applied with a predetermined clamp voltage, and a feedback capacitance through which the non-inverting input terminal of the column amplifier is connected to an output terminal of the column amplifier,
the gain of each of said column amplification units has a value determined according to a ratio between the clamp capacitance and the feedback capacitance, and
at least either the clamp capacitances or the feedback capacitances of said column amplification units in the respective columns are set to different values according to the colors of the optical filters.

3. The solid-state image pickup device according to claim 2, wherein each of said column amplification units has a transfer capacitance configured to accumulate a signal output from the column amplifier, a readout switch configured to output the signal stored in the transfer capacitance to a row readout line in accordance with a row scanning clock, and an amplifier unit configured to amplify the signal for output to the row readout line and configured to output the amplified signal as an image signal, and
at least either the clamp capacitances or the feedback capacitances or the transfer capacitances of said column amplification units in the respective columns are set to different values according to the colors of the optical filters.

4. The solid-state image pickup device according to claim 2, further including:
a first counter unit configured to count a clock signal and output a count value;
a ramp output unit configured to output a ramp waveform output corresponding to the count value output from said first counter unit;
second counter units provided in said column amplification units for the respective columns, each of said second counter units being configured to stop counting and output a count value when an output of a corresponding one of said column amplifiers coincides with the ramp waveform; and
an output unit configured to output, as an image signal, a voltage signal corresponding to the count value output from each of said second counter units.

5. The solid-state image pickup device according to claim 4, wherein slopes of ramp waveform outputs that are output from a plurality of said ramp output units are set to different values according to the colors of the optical filters.

6. The solid-state image pickup device according to claim 1, wherein the column output lines has first column output lines to which pixel signals are output from pixels in odd-numbered rows of respective columns in the plurality of pixels, and second column output lines to which pixel signals are output from pixels in even-numbered rows of respective columns in the plurality of pixels.

7. An image pickup apparatus comprising:
the solid-state image pickup device as set forth in claim 1;
a noise removal unit configured to remove noise from an image signal output from the solid-state image pickup device;
a gain adjustment unit configured to perform a gain adjustment on an output of said noise removal unit; and
an analog-to-digital conversion unit configured to perform analog-to-digital conversion on an output of said gain adjustment unit to obtain image data.
